(19) United States
(12) Patent Application Publication
(10) Pub. No.: US 2007/0092843 A1
(43) Pub. Date: Apr. 26, 2007

(54) Method to prevent anti-assist feature and side lobe from printing out

(75) Inventor: Chin Cheng Yang, Hsinchu (TW)

Correspondence Address: MARTINE PENILLA & GENCARELLA, LLP, 710 LAKEWAY DRIVE, SUITE 200, SUNNYVALE, CA, 94085, US

(73) Assignee: Macronix international Co., Ltd.

(21) Appl. No.: 11/255,761

(22) Filed: Oct. 21, 2005

(51) Int. Cl. G03F 7/26

(52) U.S. Cl. 430/322; 430/324

(57) ABSTRACT

A method for forming photo patterns on a photoresist layer is disclosed. A photoresist layer is formed over a substrate. The photoresist layer is then treated with a basic compound and is exposed. The photoresist layer can be treated with a basic compound first, and then exposed. The photoresist layer can also be exposed first, and then treated with a basic compound. The basic compound treatment for the photoresist layer can be performed by using a basic compound in the form of liquid or gas, and it can also be performed by forming a basic compound layer over the photoresist layer. The basic compound can be an amine compound. The mask used during an exposure may contain anti-assist feature (AF), and it can also be a half tone phase shift mask (HTPSM). Thus, the method can prevent anti-AF and side lobe from printing out.

### BACKGROUND OF THE INVENTION

1. Field of the Invention

The present invention relates generally to photolithography, and more particularly, to a treatment method that is capable of reducing or eliminating the anti-assist feature and side lobe printing out phenomena.

2. Description of the Related Art

Photolithography is a critical and indispensable fabrication technique that is used to transfer integrated circuit (IC) layout patterns through a mask onto predefined locations on a semiconductor substrate. In a conventional photolithographic process, the substrate is first coated with a photoresist layer that is made from a material sensitive to light radiation, such as deep ultraviolet (DUV) light. Next, the photoresist layer applied to the substrate surface undergoes a soft bake to drive off most of the solvent in the photoresist layer. Then, the substrate is exposed to light through a mask that contains the pattern corresponding to the features at a layer of the IC design. A post-exposure bake (PEB) usually follows immediately after the exposure. Finally, the photoresist layer on the substrate is developed to remove either the exposed portions for a positive photoresist or the unexposed portions for a negative photoresist, thereby producing an image corresponding to the pattern of the template on the photoresist layer. Resolution and depth of focus (DOF) are two major parameters used to measure the image quality on the photoresist layer.

As the feature critical dimensions (CD) in a pattern on a mask become smaller, the photo process window measured by DOF decreases, especially for iso patterns. The reduced photo process window lowers the quality of the image produced on the photoresist layer, and makes a photolithographic process more difficult. The small features in a pattern can also cause side lobe phenomena when a half tone phase shift mask (HTPSM) is used during a photolithographic process for the contact hole layer. The side lobe phenomena result in undesired features to be printed in the photoresist layer.

One method to improve the photo process window for small features in a pattern is to add assist feature (AF) for the line process or anti-AF for the trench process. The AF is 0% light transmittance for a binary mask, or partial light transmittance for a HTPSM, while the anti-AF is 100% light transmittance. As known in the art, the larger the size of the anti-AF, the better the photo process window for a trench process. However, the print out risk of the anti-AF will become higher as the size of the anti-AF increases, which is undesired for a photolithographic process.

In view of the foregoing, there is a need for a method that will prevent the anti-AF and side lobe from printing out, achieve good resolution, and improve the photo process window during a photolithographic process.

### SUMMARY OF THE INVENTION

Broadly speaking, the present invention fills this need by providing a photolithographic method that can prevent the anti-assist feature (AF) and side lobe from printing out, achieve good resolution, and improve the photo process window during a photolithographic process.

In accordance with one aspect of the present invention, a photolithographic method is provided. After a photoresist layer is formed over a provided substrate, the photoresist layer is treated with a basic compound and is exposed with a mask. In one embodiment, the photoresist layer is treated with the basic compound first, and then is exposed with the mask. In another embodiment, the photoresist layer is exposed with the mask first, and then is treated with the basic compound. The photoresist layer can be treated with a basic compound in the form of gas or liquid, or it can be treated by forming a basic compound layer over the photoresist layer. In one embodiment, the basic compound is an amine compound. The mask used during the exposure can contain anti-AF, and it can also be a half tone phase shift mask (HTPSM).

In accordance with another aspect of the present invention, another photolithographic method is provided. After a photoresist layer is formed over a provided substrate, the photoresist layer is exposed with a mask. The exposed photoresist layer is then treated with a basic compound. In one embodiment, the exposed photoresist layer is treated with an amine compound in the form of gas or liquid for about 0.5 second to about 180 seconds.

In accordance with a further aspect of the present invention, yet another photolithographic method is provided. After a photoresist layer is formed over a provided substrate, the photoresist layer is treated with a basic compound. Then, the treated photoresist layer is exposed with a mask. In one embodiment, the photoresist layer is treated by forming an amine compound layer over the photoresist layer for about 10 seconds to about 300 seconds.

In one embodiment, the basic compound will act to suppress features not intended by the mask from printing on a resulting photoresist mask, which will then be used for etching.

It is to be understood that the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIG. 1 is a flowchart showing the steps of a photolithographic method in accordance with one embodiment of the present invention.

FIG. 2(a)-(e) show an exemplary photolithographic trench process in accordance with one embodiment of the present invention.

FIG. 3(a)-(f) show an exemplary photolithographic trench process in accordance with one embodiment of the present invention.

### DETAILED DESCRIPTION OF THE EXEMPLARY EMBODIMENTS

Reference is made in detail to embodiments of the invention. While the invention is described in conjunction with the embodiments, the invention is not intended to be limited by these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, as is obvious to one ordinarily skilled in the art, the invention may be practiced without these specific details. In other instances, well-known methods, procedures, components, and circuits have not been described in detail so that aspects of the invention will not be obscured.

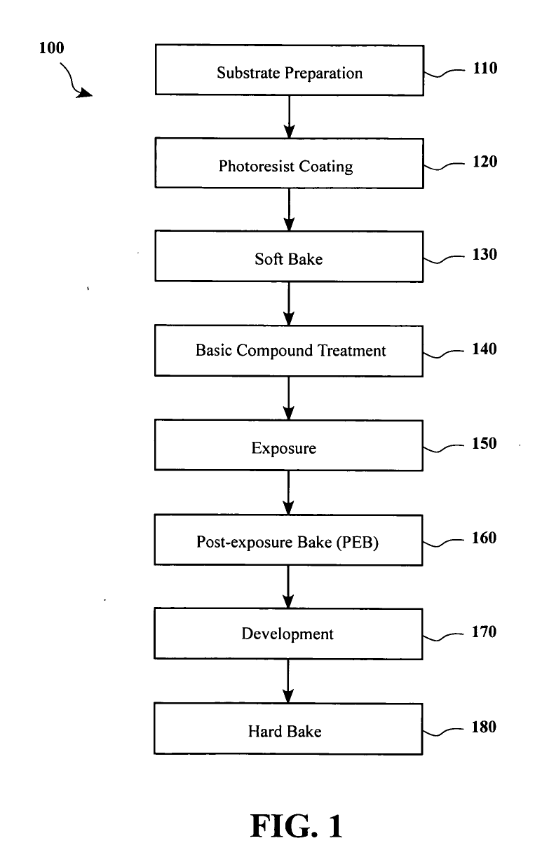

Referring initially to FIG. 1, a flowchart 100 is shown illustrating the steps of a photolithographic process in accordance with one embodiment of the present invention.

In step 110, a substrate surface is prepared to enhance the precision of the photolithographic process and to promote good adhesion between the photoresist layer and the substrate surface. One way to prepare the substrate surface is to apply a bottom antireflection coating (BARC) on the substrate surface. The BARC coating is used to planarize the substrate surface and to suppress the reflection of the exposing light from the underlying layer so as to improve the precision in the photolithographic process. Another way to prepare the substrate surface is to prime the substrate surface with hexamethyldisilazane (HMDS), which acts as an adhesion promoter.

In step 120, a photoresist layer is coated over the substrate. The coated photoresist layer is then soft baked in step 130 to drive off most of the solvent in the photoresist layer. The soft bake process improves adhesion, promotes photoresist uniformity on the substrate.

In step 140, the photoresist layer undergoes a basic compound treatment. In one embodiment, the basic compound treatment can be performed by applying a basic compound coating over the photoresist layer. In another embodiment, the basic compound treatment is performed by applying basic compound to the photoresist layer in a liquid form or a gas form. Examples of basic compounds in a liquid form include amine, TMAH (CH₃)₄NOH_{(aq)}, NH_{3(aq)}, etc. The concentration of each of the liquid formed basic compounds can be diluted and controlled by water in the amount ranging from about 0.1 wt %˜10 wt %, and the reaction temperature is about 15C˜30C. Examples of basic compounds in a gas form include HMDS vapor, NH_{3(gas)}, and CH₃NH_{2(gas)}. The concentration of each of the gas formed basic compounds can be diluted and controlled by inner gas (N₂ or Ar) in the amount ranging from about 0.1 wt %˜10 wt %, and the reaction temperature is about 15C˜30C or 90C˜150C. However, these examples should not be constructed as limiting to the scope of the basic compounds usable in the invention. In one embodiment, a property of the basic compound is that it can substantially prevent un-intended feature patterns (e.g., the aforementioned anti-AF and the side lobe) from printing out in the resulting photoresist mask. The photoresist mask, or the mask, is a reticle, typically a glass reticle with defined patterns.

In step 150, the substrate with the treated photoresist layer is aligned with a patterned mask and then exposed to controlled UV light to transfer the pattern on the mask to the photoresist coated substrate. The light energy activates the photosensitive components of the photoresist layer. The substrate surface could be bare silicon but usually has an existing pattern previously defined on its surface.

In step 160, a post-exposure bake (PEB) is performed for the photoresist coated substrate immediately after the exposure. In step 170, the soluble areas of the photoresist layer are dissolved by liquid developer chemicals, leaving visible patterns of islands and windows on the substrate surface. In step 180, a post-development thermal bake, referred to as hard bake, is performed to evaporate the remaining photoresist solvent and improve the adhesion of the photoresist layer to the substrate surface.

For the photolithographic method demonstrated in FIG. 1, the exposure step (step 150) and the basic compound treatment step (step 140) could be reversed.

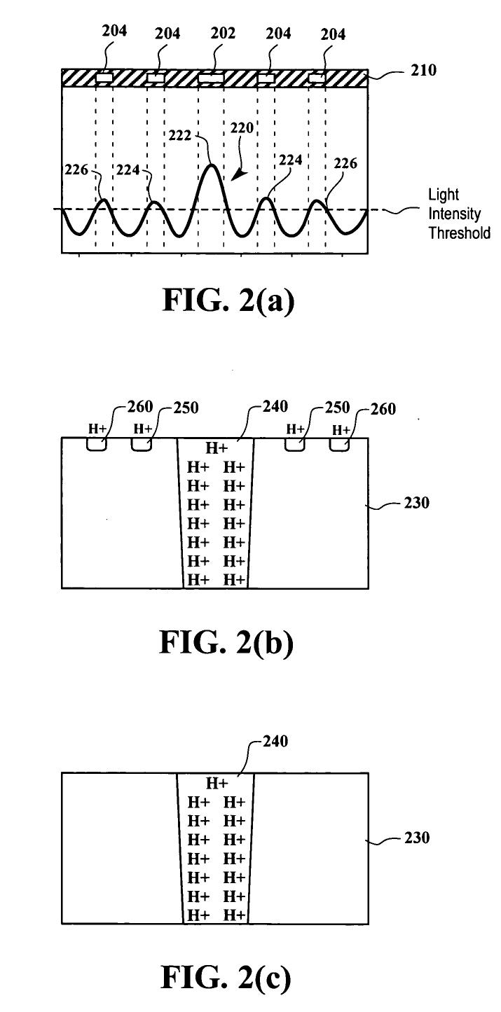

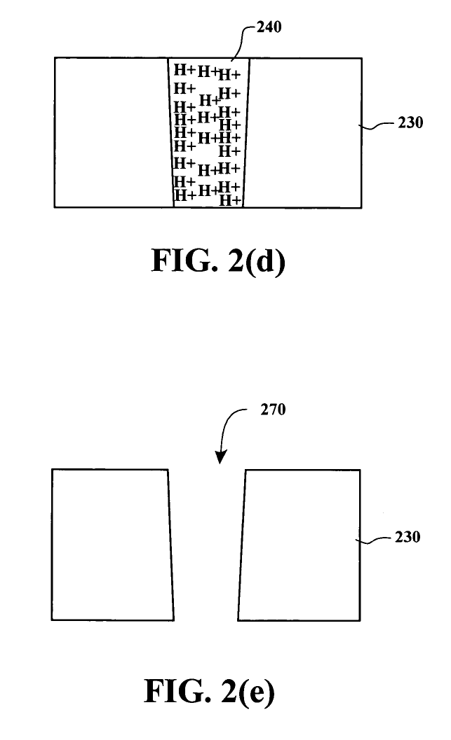

Referring now to FIG. 2(a)-(e), an exemplary photolithographic trench process is shown in accordance with one embodiment of the present invention. The “H+” in FIG. 2(b)-(d) represents the photo acid produced during the photolithographic process.

FIG. 2(a) shows a trench mask 210 and its light intensity graph 220. The trench mask 210 includes a feature opening 202 and four anti-AF openings 204. The four anti-AF openings 204 are used to improve the photo process window during a photolithographic process. The light intensity graph 220 illustrates the light intensity amplitude with respect to distance, when the trench mask 210 is used during a photolithographic process. As shown, the light intensity graph 220 includes a main component 222 corresponding to the feature opening 202, and the components 224 and 226 corresponding to the four anti-AF openings 204. The dashed line in FIG. 2(a) represents the light intensity threshold. The main component 222 is desired since it corresponds to a feature of an integrated circuit design, whereas the components 224 and 226 needs to be controlled to limit the photo acid produced on the surface of a photoresist layer. It is desired that the intensity amplitudes of the components 224 and 226 of the light intensity graph 220 do not exceed the light intensity threshold. However, as the size of the feature opening 202 decreases, the photo process window of the photolithographic process also decreases. In order to improve the process window, larger size of the anti-AF is desired, which leads to more intensity amplitudes for the components 224 and 226 of the light intensity graph 220. As shown, the components 224 and 226 of the light intensity graph 220 exceed the light intensity threshold, which will produce photo acid on the surface of a photoresist layer after the photoresist layer is exposed.

FIG. 2(b) shows a photoresist layer 230 after a light exposure with the trench mask 210. As shown, after the photoresist layer 230 is exposed by using the trench mask 210, one main exposed region 240 and four exposed regions 250 and 260 are formed on the photoresist layer 230. The main exposed region 240, corresponding to the feature opening 202, is created by the main component 222 of the light intensity graph 220, while the exposed regions 250 and 260, corresponding to the anti-AF openings 204, are created by the components 224 and 226 of the light intensity graph 220, respectively.

Because the strong intensity amplitude of the main component 222 of the light intensity graph 220, the main exposed region 240 is formed across the thickness of the photoresist layer 230. In contrast, due to the weak intensity amplitudes of the components 224 and 226 of the light intensity graph 220, the exposed regions 250 and 260 are only formed on the surface of the photoresist layer 230. The main exposed region 240 contains much more photo acid than the exposed regions 260 and 250. The exposed regions 250 contain slightly more photo acid than the exposed regions 260, due to the slightly stronger light intensity amplitudes of the components 224 in comparison to the ones of the components 226. The photo acid in the exposed regions 250 and 260 are undesired because they will form undesired patterns on the photoresist layer after the photoresist layer is developed.

As shown in FIG. 2(c), after the basic compound treatment, the basic property of the basic compound neutralizes the acidic property of the photo acid in the exposed regions 250 and 260. As a result, the exposed regions 250 and 260 no longer contain photo acid and disappear. Although the amount of the photo acid in the main exposed region 240 also reduces after the basic compound treatment, the effect of the photo acid reduction in the main exposed region 240 can be controlled by limiting the basic compound treatment time. In one embodiment, the basic compound treatment is performed by an amine compound in the form of liquid or gas, and the treatment time ranges from about 0.5 second to about 180 seconds. As a result, the photo acid reduction has very limited effect for the main exposed region 240 due to the large amount of photo acid existed in the main exposed region 240.

FIG. 2(d) shows the photoresist layer 230 after the PEB process. As shown, the amount of the photo acid in the main exposed region 240 increases after the PEB process. The photoresist layer 230 is then developed to create the pattern in the photoresist layer 230 on the substrate surface. As shown in FIG. 2(e), the main exposed region 240 of the photoresist layer 230 is dissolved by liquid developer chemicals, leaving the visible feature 270 in the photoresist layer 230.

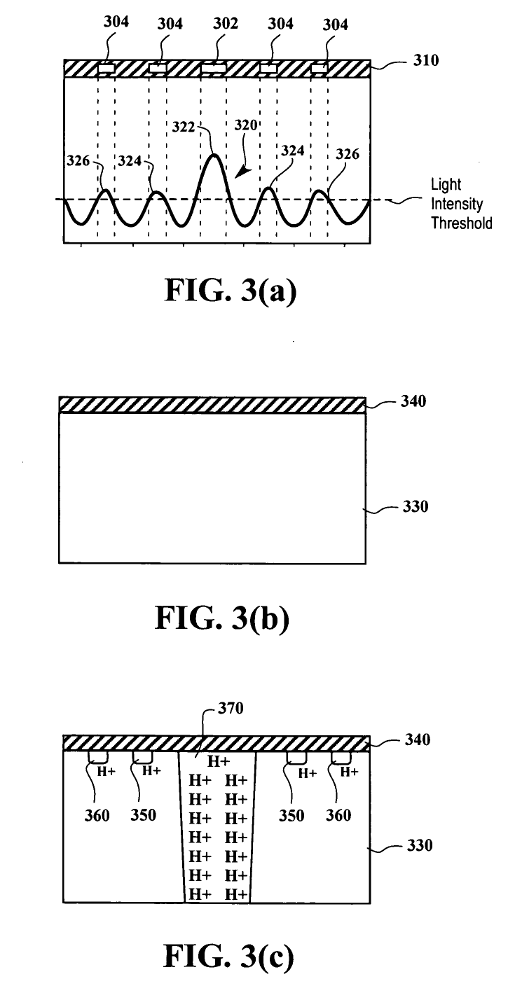

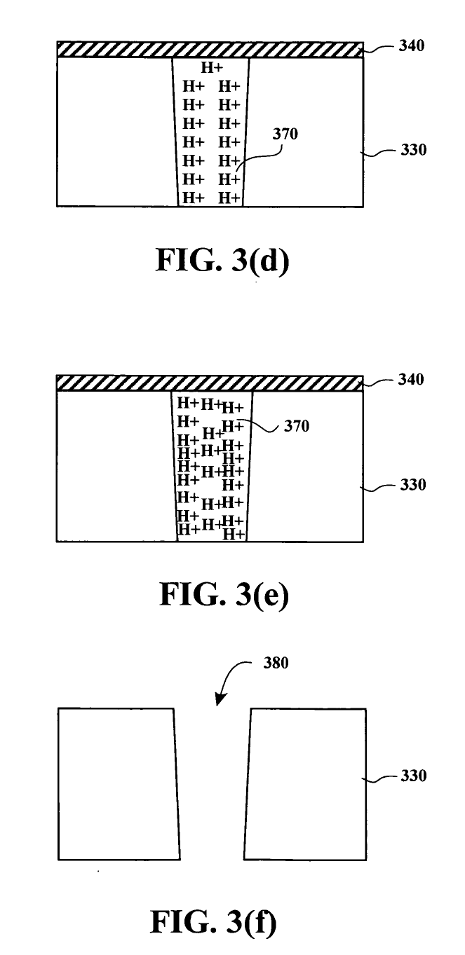

Referring now to FIG. 3(a)-(f), an exemplary photolithographic trench process is shown in accordance with one embodiment of the present invention. The “H+” in FIG. 3(c)-(e) represents the photo acid produced during the photolithographic process.

FIG. 3(a) shows a trench mask 310 and its light intensity graph 320. The trench mask 310 includes a feature opening 302 and four anti-AF openings 304. The four anti-AF openings 304 are used to improve the photo process window during a photolithographic process. The light intensity graph 320 illustrates the light intensity amplitude with respect to distance, when the trench mask 310 is used during a photolithographic process. As shown, the light intensity graph 320 includes a main component 322 corresponding to the feature opening 302, and the components 324 and 326 corresponding to the four anti-AF openings 304. The dashed line in FIG. 3(a) represents the light intensity threshold.

The main component 322 of the light intensity graph 320 is desired since it corresponds to a feature of an integrated circuit design, whereas the components 324 and 326 of the light intensity graph 320 need to be controlled in order to minimize the amount of photo acid produced on the surface of the photoresist layer after the photoresist layer is exposed by using the trench mask 310. It is desired that the intensity amplitudes of the components 324 and 326 of the light intensity graph 320 do not exceed the light intensity threshold. However, as the size of the feature opening 302 decreases, the photo process window of the photolithographic process also decreases. In order to improve the process window, larger size of the anti-AF is desired, which leads to more intensity amplitudes for the components 324 and 326 of the light intensity graph 320. As shown, the components 324 and 326 of the light intensity graph 320 exceed the light intensity threshold, which will produce photo acid on the surface of a photoresist layer after the photoresist layer is exposed.

As shown in FIG. 3(b), a basic compound layer 340 is formed over a photoresist layer 330. FIG. 3(c) shows one main exposed region 370 and four exposed regions 350 and 360 are formed on the photoresist layer 330 after the photoresist layer 330 is exposed with the trench mask 310. The main exposed region 370, corresponding to the feature opening 302, is created by the main component 322 of the light intensity graph 320, while the exposed regions 350 and 360, corresponding to the anti-AF openings 304, are created by the components 324 and 326 of the light intensity graph 320, respectively.

Because of the strong intensity amplitude of the main component 322 of the light intensity graph 320, the main exposed region 370 is formed across the thickness of the photoresist layer 330. Although the intensity amplitudes of the components 324 and 326 exceed the light intensity threshold, the components 324 and 326 are much weaker in comparison with the main component 322. Therefore, the exposed regions 350 and 360, respectively created by the components 324 and 326, are only formed on the surface of the photoresist layer 330. The main exposed region 370 contains much more photo acid than the exposed regions 350 and 360. The exposed regions 350 contain slightly more photo acid than the exposed regions 360, because the components 324 are slightly stronger than the components 326. The photo acid in the exposed regions 350 and 360 are undesired because they will form undesired patterns on the photoresist layer after development if the exposed regions 350 and 360 are untreated by the basic compound treatment.

As shown in FIG. 3(d), the photo acid of the main exposed region 370 and the four exposed regions 350 and 360 on photoresist layer 330 reacted with the basic property of the basic compound layer 340. Because the exposed regions 350 and 360 contains a very limited amount of photo acid, after the basic property of the basic compound layer 340 neutralizes the photo acid in the exposed regions 350 and 360, the exposed regions 350 and 360 disappear because they no longer contain photo acid. Although the amount of the photo acid in the main exposed region 370 also reduces after the basic property of the basic compound layer 340 reacts with the photo acid in the main exposed region 370, the effect of the photo acid reduction in the main exposed region 370 can be controlled by limiting the basic compound treatment time. In one embodiment, the basic compound layer 340 is an amine layer and the basic compound treatment time ranges from about 10 seconds to about 300 seconds. As a result, the photo acid reduction has very limited effect for the main exposed region 370 due to the large amount of photo acid produced by the main component 322 of the light intensity graph 320.

As shown in FIG. 3(e), the amount of the photo acid in the main exposed region 370 increases after the PEB process. Then, the photoresist layer 330 is developed to create the pattern in the photoresist layer 330. As shown in FIG. 3(f), the main exposed region 370 of the photoresist layer 330 and the basic compound layer 340 are dissolved by liquid developer chemicals. Thus, the basic compound layer 340 is removed and a visible feature 380 is formed in the photoresist layer 330.

Because the present invention can prevent anti-AF from printing out, the larger size of anti-AF can be utilized in order to improve the photo process window during a photolithographic process for small feature patterns, especially for iso patterns. As a result, the through focus critical dimension (CD) uniformity and the resolution and image contrast for a photolithographic process can also be improved. Furthermore, the present invention can prevent the side lobe from printing out during a photolithographic process for a contact hole layer when a half tone phase shift mask (HTPSM) is used.

The foregoing descriptions of specific embodiments of the invention have been presented for purposes of illustration and description. They are not intended to be exhaustive or to limit the invention to the precise forms disclosed. Obviously, many modifications and variations are possible in light of the above teaching. The embodiments were chosen and described in order to explain the principles and the application of the invention, thereby enabling others skilled in the art to utilize the invention in its various embodiments and modification s according to the particular purpose contemplated. The scope of the invention is intended to be defined by the claims appended hereto and their equivalents.

What is claimed is:

1. A method for forming photo patterns, comprising:
providing a substrate;
forming a photoresist layer over the substrate; and
performing a basic compound treatment of the photoresist layer and a light exposure of the photoresist layer through a mask for patterning the photoresist layer.

2. The method for forming photo patterns as recited in claim 1, wherein the basic compound treatment is performed using a basic compound in a gas form or a liquid form.

3. The method for forming photo patterns as recited in claim 1, wherein the basic compound treatment is performed by forming a basic compound layer over the photoresist layer.

4. The method for forming photo patterns as recited in claim 1, wherein the basic compound treatment is performed by an amine compound.

5. The method for forming photo patterns as recited in claim 1, wherein the performing of the basic compound treatment and the exposure comprises,
performing the basic compound treatment of the photoresist layer followed by the light exposure through the mask.

6. The method for forming photo patterns as recited in claim 5, wherein the basic compound treatment is performed by forming an amine compound layer over the photoresist layer for about 10 seconds to about 300 seconds.

7. The method for forming photo patterns as recited in claim 1, wherein the performing of the basic compound treatment and the exposure comprises,
performing the light exposure through the mask followed by the basic compound treatment.

8. The method for forming photo patterns as recited in claim 7, wherein the basic compound treatment is performed by treating the photoresist layer with an amine compound in a gas form or a liquid form for about 0.5 second to about 180 seconds.

9. The method for forming photo patterns as recited in claim 1, wherein the mask is a half tone phase shift mask (HTPSM).

10. The method for forming photo patterns as recited in claim 1, wherein the mask contains anti-assist features.

11. The method for forming photo patterns as recited in claim 1, further comprising:
preparing the substrate before the forming of the photoresist layer;
soft baking the photoresist layer after the forming of the photoresist layer;
post-exposure baking the photoresist layer after the basic compound treatment and the exposure;
developing the photoresist layer; and
hard baking the photoresist layer.

12. A method for forming photo patterns over a substrate, comprising:
forming a photoresist layer over the substrate;
performing a exposure with a mask for the photoresist layer; and
performing a basic compound treatment for the photoresist layer to suppress features not intended by the mask from printing on a resulting photoresist mask.

13. The method for forming photo patterns as recited in claim 12, wherein the basic compound treatment is performed by treating the photoresist layer with a basic compound in a gas form or a liquid form.

14. The method for forming photo patterns as recited in claim 12, wherein the basic compound treatment is performed by forming a basic compound layer over the photoresist layer.

15. The method for forming photo patterns as recited in claim 12, wherein the basic compound treatment is performed by treating the photoresist layer with an amine compound in a gas form or a liquid form for about 0.5 second to about 180 seconds.

16. The method for forming photo patterns as recited in claim 12, further comprising:
preparing the substrate before the forming of the photoresist layer;
soft baking the photoresist layer after the forming of the photoresist layer;
post-exposure baking the photoresist layer after the basic compound treatment;
developing the photoresist layer to define the resulting photoresist mask; and
hard baking the resulting photoresist mask.

17. A method for forming photo patterns, comprising:
providing a substrate;
forming a photoresist layer over the substrate;
performing a basic compound treatment on the photoresist layer, the basic compound treatment suppressing unwanted features from impacting a resulting photoresist mask; and
performing an exposure with a mask for the photoresist layer.

18. The method for forming photo patterns as recited in claim 17, wherein the basic compound treatment is performed by treating the photoresist layer with a basic compound in a gas form or a liquid form.

19. The method for forming photo patterns as recited in claim 17, wherein the basic compound treatment is performed by forming a basic compound layer over the photoresist layer.

20. The method for forming photo patterns as recited in claim 17, wherein the basic compound treatment is performed by forming an amine compound layer over the photoresist layer for about 10 seconds to about 300 seconds.

21. The method for forming photo patterns as recited in claim 17, further comprising:
preparing the substrate before the forming of the photoresist layer;
soft baking the photoresist layer after the forming of the photoresist layer;
post-exposure baking the photoresist layer after the exposure;
developing the photoresist layer; and
hard baking the photoresist layer.
